(19) United States
(12) Patent Application Publication
(10) Pub. No.: US 2019/0390556 A1
(43) Pub. Date: Dec. 26, 2019

(54) COMPOSITE COATING LAYER HAVING IMPROVED EROSION RESISTANCE AND TURBINE COMPONENT INCLUDING THE SAME

(71) Applicant: DOOSAN HEAVY INDUSTRIES & CONSTRUCTION CO., LTD., Changwon-si (KR)

(72) Inventors: In Soo KIM, Changwon-si (KR); Chan Young PARK, Daejeon (KR)

(21) Appl. No.: 16/410,017

(22) Filed: May 13, 2019

(30) Foreign Application Priority Data
Jun. 25, 2018 (KR) 10-2018-0072503

(51) Int. Cl. F01D 5/28; C23C 14/06; C23C 14/30; C23C 14/34; C23C 14/32; F01D 25/00

(52) U.S. Cl. CPC F01D 5/288; C23C 14/0617; C23C 14/0641; C23C 14/30; C23C 14/34; C23C 14/325; F05D 2300/133; F01D 25/007; F05D 2220/31; F05D 2220/32; F05D 2230/90; F05D 2240/12; F05D 2240/30; F01D 25/005

(57) ABSTRACT

Provided are a composite coating layer having improved erosion resistance and a turbine component including the same. The composite coating layer may include a TiN layer; and a TiAlN layer, wherein the composite coating layer is formed by alternately stacking the TiN layer and the TiAlN layer, and a total number of layers including the TiN layer and the TiAlN layer is 6 to 18, whereby the composite coating layer is capable of exhibiting high erosion resistance, high hardness, superior high-cycle fatigue characteristics and low surface roughness. Moreover, the turbine component including the composite coating layer is also capable of manifesting improved properties, such as high erosion resistance, high hardness, superior high-cycle fatigue characteristics and low roughness, thus remarkably increasing lifespan characteristics.

### CROSS REFERENCE TO RELATED APPLICATION

This application claims priority from Korean Patent Application No. 10-2018-0072503, filed on Jun. 25, 2018, the entire disclosure of which is incorporated herein by reference in its entirety.

### BACKGROUND

### 1. Field

Apparatuses and methods consistent with exemplary embodiments relate to a composite coating layer having improved erosion resistance and a turbine component including the same, and more particularly to a composite coating layer, which is provided in the form of multiple layers by alternately stacking a TiN layer and a TiAlN layer and to a turbine component including the same.

### 2. Description of the Related Art

Metal components are widely used in a variety of industrial fields due to the unique high rigidity thereof. Also, since metal components are used in various environments, a coating layer is formed on metal components to improve the properties of the metal components, such as erosion resistance, corrosion resistance, heat resistance, and oxidation resistance.

For example, for a metal component used in a high-pressure or medium-pressure turbine, a coating process for imparting erosion resistance to a substrate is performed, because the surface of the substrate is easily eroded by solid or liquid particles.

In particular, for a high-pressure steam turbine used in a power generation boiler, iron oxide (Fe₃O₄) generated during the operation of the power generation boiler collides with a steam turbine bucket, which is a rotating body, and with a nozzle, which is a fixed body. This causes erosion, and thus the turbine has to be coated with a material having high erosion resistance at a high temperature.

In general, a hard metal material is used for a coating layer to increase the erosion resistance of metal components, and a coating layer is formed on a substrate through chemical vapor deposition (CVD), plasma-enhanced chemical vapor deposition (PCVD) or physical vapor deposition (PVD).

Previously, in order to increase the erosion resistance of metal components, a coating layer comprising a ceramic material, such as alumina, titania, or chromia is formed on the surface of a metal component using a thermal spraying technique, for example, air plasma spraying (APS), and high-velocity oxygen fuel (HVOF) spraying, etc. However, such a coating layer increases the surface roughness of the metal component and is limitedly able to increase surface hardness, thus causing various problems in the operation of the turbine, and consequently shortening the operating lifespan of the metal component.

Many attempts have been made to enhance the aerodynamic efficiency of the steam turbine components by reducing the surface roughness of the coating layer to increase erosion resistance, but methods capable of satisfying all of economic benefits and workability as well as realizing the desired properties of the coating layer have not yet been developed.

Recently, thorough research has been conducted into coating layers for metal components used in turbines to lower the surface roughness, to enhance the surface hardness, and to increase the erosion resistance thereof to thereby prolong the operating lifespan, but satisfactory coating layers have still not been developed.

### SUMMARY

Aspects of one or more exemplary embodiments provide a composite coating layer, which is formed in multiple layers by alternately stacking a TiN layer and a TiAlN layer, to increase the erosion resistance of a coating layer formed on the surface of a tool, and a turbine component including the same.

Additional aspects will be set forth in part in the description which follows and, in part, will become apparent from the description, or may be learned by practice of the exemplary embodiments.

According to an aspect of an exemplary embodiment, there is provided a composite coating layer including: a TiN layer; and a TiAlN layer, wherein the composite coating layer may be formed by alternately stacking the TiN layer and the TiAlN layer, and a total number of layers comprising the TiN layer and the TiAlN layer may be 6 to 18.

The total number of layers comprising the TiN layer and the TiAlN layer, which are alternately stacked, may be 12.

The thickness of the TiN layer may range from 0.1 to 0.5 μm.

The thickness of the TiAlN layer may range from 0.7 to 3.0 μm.

The total thickness of the composite coating layer may range from 5.1 to 24.0 μm.

The TiAlN layer may include 50.3 to 61.5 wt % of Ti, 19.6 to 26.2 wt % of Al, and 18.8 to 24.3 wt % of N.

The uppermost layer of the composite coating layer may be a TiAlN layer.

The thickness of the uppermost TiAlN layer may range from 1.0 to 6.0 μm.

According to an aspect of another exemplary embodiment, there is provided a turbine component including: a substrate; and a composite coating layer disposed on the substrate, wherein the composite coating layer may be formed by alternately stacking a TiN layer and a TiAlN layer on the substrate, and a total number of layers comprising the TiN layer and the TiAlN layer may be 6 to 18.

The total number of layers comprising the TiN layer and the TiAlN layer, which are alternately stacked, may be 12.

The substrate may be chromium steel or a nickel alloy.

The thickness of the TiN layer may range from 0.1 to 0.5 μm.

The thickness of the TiAlN layer may range from 0.7 to 3.0 μm.

The total thickness of the composite coating layer may range from 5.1 to 24.0 μm.

The TiAlN layer may include 50.3 to 61.5 wt % of Ti, 19.6 to 26.2 wt % of Al, and 18.8 to 24.3 wt % of N.

The uppermost layer of the composite coating layer may be a TiAlN layer.

The thickness of the uppermost TiAlN layer may range from 1.0 to 6.0 μm.

The turbine component may be a bucket or a nozzle.

The turbine component may be used for a turbine blade or a turbine vane.

The turbine component may be used for an electrical turbine, a gas turbine, or a steam turbine.

As described above, according to one or more exemplary embodiments, a composite coating layer is formed by alternately stacking a TiN layer and a TiAlN layer, in which the total number of layers comprising the TiN and TiAlN layers is 6 to 18, whereby the composite coating layer is capable of exhibiting high erosion resistance, high hardness, superior high-cycle fatigue characteristics and low surface roughness. Moreover, a turbine component having the composite coating layer can also attain the above properties, thereby remarkably increasing lifespan characteristics.

However, the effects of the disclosure are not limited to the foregoing, and other effects not mentioned herein will be able to be clearly understood by those skilled in the art from the following description.

### BRIEF DESCRIPTION OF THE DRAWINGS

The above and other aspects will become more apparent from the following description of the exemplary embodiments with reference to the accompanying drawings, in which:

FIG. 1 shows a composite coating layer according to an exemplary embodiment;

FIGS. 2A to 2C are scanning electron microscopy (SEM) images showing the cross-sections of test specimens in which a composite coating layer according to an exemplary embodiment is formed on each of chromium steel (9Cr), chromium steel (12Cr) and a nickel alloy;

FIG. 3 shows optical images of the surfaces of test specimens for measuring the adhesion of the composite coating layer;

FIGS. 4A and 4B are graphs showing the high-cycle fatigue characteristics of test specimens;

FIG. 5 is a graph showing the residual stress of test specimens;

FIGS. 6A to 6E are graphs showing the erosion characteristics due to solid particles of test specimens;

FIG. 7 is a graph showing the surface roughness of test specimens; and

FIG. 8 is a graph showing the hardness of test specimens.

### DETAILED DESCRIPTION

The terms or words used in the specification, including technical and scientific terms, have the same meanings as would be generally understood by those skilled in the relevant art. However, these terms may vary depending on the intentions of the person skilled in the art, legal or technical interpretation, and the emergence of new technologies. In addition, some terms are arbitrarily selected by the applicant. These terms may be construed per the meaning defined or described herein and, unless otherwise specified, may be construed on the basis of the entire contents of this specification and common technical knowledge in the art.

In this specification, terms such as “comprising” and “including” should be construed as designating that there are such features, numbers, operations, elements, components or a combination thereof in the specification, not to exclude the existence or possibility of adding one or more of other features, numbers, operations, elements, components or a combination thereof.

Hereinbelow, it is understood that expressions such as “at least one of a, b or c” and “a, b, and/or c” means only a, only b, only c, both a and b, both a and c, both b and c, all of a, b, and c, or variations thereof.

Hereinafter, embodiments will be described in detail with reference to the accompanying drawings so that those skilled in the art can easily carry out the disclosure. However, the disclosure may be embodied in many different forms and is not limited to the embodiments described herein. In order to clearly illustrate the disclosure in the drawings, some of the elements that are not essential to the complete understanding of the disclosure may be omitted, and like reference numerals refer to like elements throughout the specification.

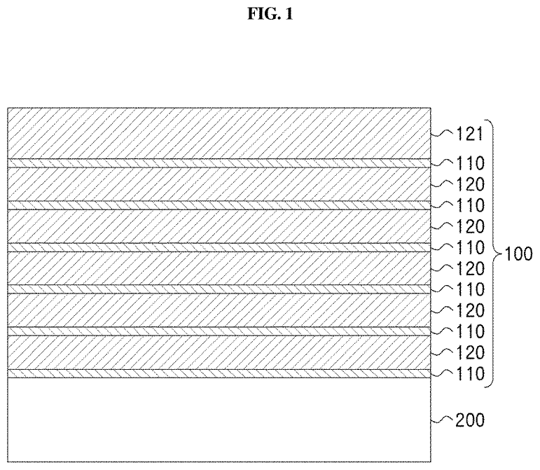

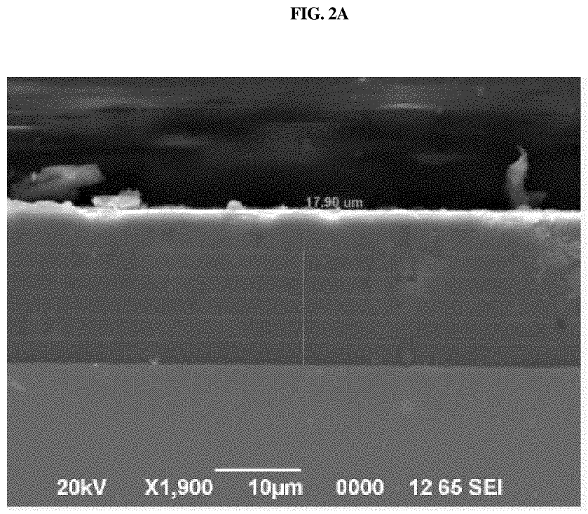

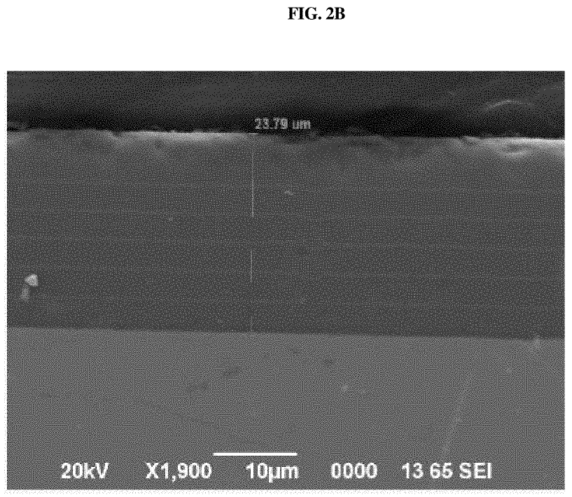

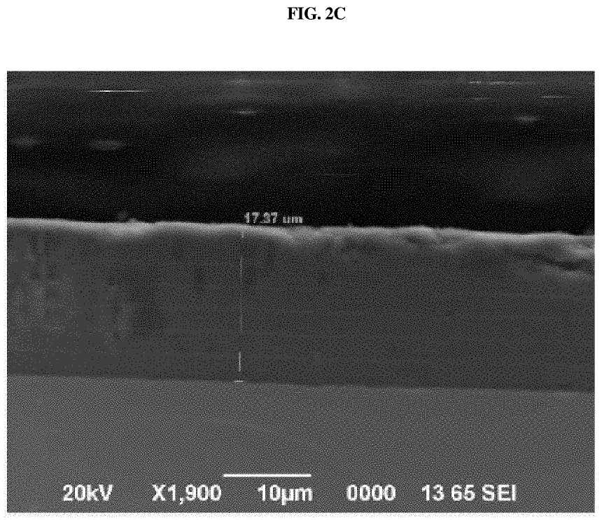

FIG. 1 shows a composite coating layer 100 according to an exemplary embodiment.

With reference to FIG. 1, the composite coating layer 100 according to an exemplary embodiment is formed by alternately stacking a TiN layer 110 and a TiAlN layer 120.

TiN, which constitutes the TiN layer 110, has a cubic crystal structure of an octahedron, in which Ti and N atoms are strongly ion-bonded, and is thus thermally and chemically stable and has high oxidation resistance and a low friction coefficient. TiN may be applied as a material for a diffusion barrier layer of a semiconductor device or an abrasion-resistant coating material of a metal tool.

However, when a coating layer of a metal tool operating in a high-temperature and high-pressure environment such as a turbine is composed of a TiN layer 110 alone, it is vulnerable to erosion due to solid particles, resulting in a reduction in the lifespan of the turbine.

On the other hand, TiAlN constituting the TiAlN layer 120 is excellent in thermal and chemical stability at a high temperature and has low thermal conductivity and high hardness, and thus may be used for a coating layer of a metal tool for various uses.

However, in case in which the coating layer is composed exclusively of the TiAlN layer 120, the adhesion of the coating layer to a substrate 200 may decrease, thus causing a problem in which the coating layer is stripped from the substrate 200.

Accordingly, the composite coating layer 100 formed by alternately stacking the TiN layer 110 and the TiAlN layer 120 is used, whereby the composite coating layer 100 that is increased in adhesion to the substrate 200, adhesion between the TiN layer 110 and the TiAlN layer 120, and erosion resistance is provided.

As described above, the composite coating layer 100 according to an exemplary embodiment may be formed by alternately stacking the TiN layer 110 and the TiAlN layer 120. Here, the total number of layers comprising the TiN layer 110 and the TiAlN layer 120 is preferably 6 to 18. If the total number of layers is less than 6, high erosion resistance and low surface roughness may be exhibited but hardness is decreased, undesirably lowering abrasion resistance. On the other hand, if the total number of layers exceeds 18, hardness may decrease and thus erosion characteristics may deteriorate, and moreover, surface roughness may increase, undesirably lowering the aerodynamic efficiency of the metal tool.

More preferably, the total number of layers comprising the TiN layer 110 and the TiAlN layer 120 is 12. When the total number of layers is 12, the lowest surface roughness, excellent erosion resistance and the highest hardness may result, ultimately maximizing the physical properties of metal tools.

The thickness of the TiN layer 110 may range from 0.1 to 0.5 μm. If the thickness of the TiN layer 110 is less than 0.1 μm, bonding force between the TiN layer 110 and the TiAlN layer 120 may decrease and it may be difficult to obtain impact resistance, stress relief, and crack propagation reduction effects. On the other hand, if the thickness thereof exceeds 0.5 μm, adhesiveness to the substrate 200 may decrease due to the excessive thickness, and thus the adhesion and fatigue resistance may deteriorate.

The thickness of the TiAlN layer 120 may range from 0.7 to 3.0 μm. If the thickness of the TiAlN layer 120 is less than 0.7 μm, it is difficult to increase erosion resistance and durability. On the other hand, if the thickness thereof exceeds 3.0 μm, adhesion to the TiN layer 110 may decrease.

The total thickness of the composite coating layer 100, in which the number of stacked TiN layer 110 and TiAlN layer 120 is 6 to 18, preferably ranges from 5.1 to 24.0 μm. If the total thickness of the composite coating layer 100 is less than 5.1 μm, it is difficult to obtain sufficient erosion resistance. On the other hand, if the total thickness thereof exceeds 24.0 μm, it is difficult to obtain additional erosion resistance or an improvement in physical properties due to the excessive thickness, and problems such as cracking may occur and the lifespan of the metal tool having the composite coating layer 100 may be reduced.

The TiAlN layer 120 may comprise 50.3 to 61.5 wt % of Ti, 19.6 to 26.2 wt % of Al, and 18.8 to 24.3 wt % of N.

Here, when the concentration ratio of Ti and Al of the TiAlN layer 120 falls in the above range, higher hardness and elastic modulus than conventional coatings and a superior residual stress relaxation effect are exhibited.

On the other hand, if the concentration ratio of Ti and Al of the TiAlN layer 120 falls out of the above range, it is difficult to obtain properties such as high fatigue resistance, low roughness and high hardness.

A TiAlN layer is disposed as an uppermost layer of the composite coating layer 100, and the thickness of the uppermost TiAlN layer 121 may be greater than that of other TiAlN layer 120. For example, the thickness of the uppermost TiAlN layer 121 may be 1.0 to 6.0 μm. If the thickness thereof is less than 1.0 μm, erosion resistance may be remarkably decreased, making it difficult to withstand erosion damage when used for components such as high-pressure turbines. On the other hand, if the thickness thereof exceeds 6.0 μm, the frequency of occurrence of defects in the composite coating layer may increase, undesirably reducing the lifespan of the metal components.

While the process for alternately depositing the TiN layer 110 and the TiAlN layer 120 is not particularly limited, for example, a physical vapor deposition (PVD) process may be used. Examples of the physical vapor deposition (PVD) process may include electron beam physical vapor deposition (EB-PVD), cathodic arc physical vapor deposition (CA-PVD), and sputtering.

The composite coating layer 100 described above is excellent in erosion resistance at high temperatures, and may exhibit strong adhesion to the substrate 200, superior high-cycle fatigue characteristics, superior coating stress characteristics, high hardness and low surface roughness.

Another exemplary embodiment pertains to a turbine component, comprising a substrate 200 and the composite coating layer 100 formed on the substrate 200.

The substrate 200 may be selected from the group consisting of chromium steel and nickel alloy, which have excellent abrasion resistance. Here, chromium steel may be stainless steel containing 9 wt % of chromium or stainless steel containing 12 wt % of chromium.

The turbine component may be a bucket or a nozzle.

The turbine component may be used for turbine blades or turbine vanes.

In addition, the turbine component may be used in electrical turbines, gas turbines, or steam turbines.

A better understanding of one or more exemplary embodiments will be given through the following examples, which are merely set forth to illustrate the present disclosure but are not to be construed as limiting the scope of the present disclosure.

### Preparation Example

Chromium steel of 9Cr and 12Cr and nickel alloy test specimens having a size of 70×40×5 mm are prepared, and a single coating layer made of TiAlN or a composite coating layer 100 comprising alternately deposited TiN and TiAlN layers is formed on the surface of each of the test specimens using cathodic arc physical vapor deposition (CA-PVD). Then, the thickness and the number of layers of the single coating layer or the composite coating layer 100 formed on each test specimen are measured using a Calotest device made by CSEM Instruments SA. The results are shown in Table 1 below. Here, the term “coating layer” is defined as a term including both the single coating layer and the composite coating layer 100.

TABLE 1

| | | Composition | | Thickness (μm) | | | |
|---|---|---|---|---|---|---|---|
| | Number of | Odd | Even | Odd | Even | Uppermost | Coating |
| | layers | layer | layer | layer | layer | TiAlN layer | layer |
| Comparative | 1 | TiAlN | | 10 ± 2 | | — | 10 |
| Example 1 | | | | | | | |
| Comparative | 1 | TiAlN | | 15 ± 5 | | — | 15 |
| Example 2 | | | | | | | |
| Comparative | 4 | TiN | TiAlN | 0.3 ± 0.2 | 10 ± 2 | 10 ± 2 | 20.6 |
| Example 3 | | | | | | | |
| Example 1 | 12 | TiN | TiAlN | 0.3 ± 0.2 | 2 ± 1 | 4 ± 2 | 15.8 |
| Comparative | 20 | TiN | TiAlN | 0.3 ± 0.2 | 2 ± 1 | 4 ± 2 | 25 |
| Example 4 | | | | | | | |
| Comparative | 4 | Ti | TiAlN | 0.3 ± 0.2 | 10 ± 2 | 10 ± 2 | 20.6 |
| Example 5 | | | | | | | |
| Comparative | 12 | Ti | TiAlN | 0.3 ± 0.2 | 2 ± 1 | 4 ± 2 | 15.8 |
| Example 6 | | | | | | | |
| Comparative | 20 | Ti | TiAlN | 0.3 ± 0.2 | 2 ± 1 | 4 ± 2 | 25 |
| Example 7 | | | | | | | |
| Comparative | 28 | TiN | TiAlN | 0.2 ± 0.1 | 1 ± 0.1 | 2 ± 0.5 | 17.2 |
| Example 8 | | | | | | | |

### [Test Example 1] Measurement of Hardness and Adhesion

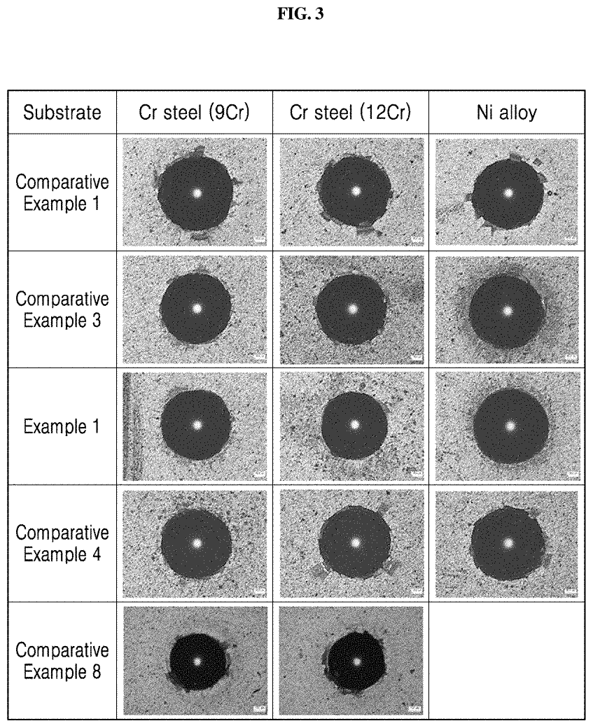

In accordance with the German Federal Technologist's Guideline VDI 3198, hardness is measured using the Rockwell-C hardness test method. The results are shown in Table 2 below. Furthermore, SEM images of the surfaces of test specimens subjected to the Rockwell-C hardness test are shown in FIG. 3, and the Rockwell-C chart, which is a standard of the HF value (i.e., value of adhesion) depending on the surface morphology, is compared with the above SEM images to determine the HF value of each test specimen. The results are summarized in Table 2 below. These results mean that the adhesion decreases from HF1 to HF6.

This hardness measurement test is carried out by applying a 150 kg preload to the coating layer using a diamond indenter. The radius of the diamond indenter is 0.2 mm, and the angle of the indenter is 120°.

TABLE 2

| Substrate | | Cr steel | | Cr steel | | | |
|---|---|---|---|---|---|---|---|
| | Number of layers for | (9Cr) | | (12Cr) | | Ni alloy | |
| Items | coating layer | Hardness | Adhesion | Hardness | Adhesion | Hardness | Adhesion |
| Comparative | 1 | 29 | HF3 | 34 | HF3~4 | 32 | HF3 |
| Example 1 | | | | | | | |
| Comparative | 4 | 29 | HF2 | 34 | HF2 | 33 | HF2 |
| Example 3 | | | | | | | |
| Example 1 | 12 | 29.5 | HF1 | 33 | HF1 | 33 | HF1 |
| Comparative | 20 | 28.5 | HF2 | 35 | HF3 | 33 | HF3 |
| Example 4 | | | | | | | |
| Comparative | 28 | — | HF3~4 | — | HF3~4 | | |
| Example 8 | | | | | | | |

Referring to FIG. 3 and Table 2, it is confirmed that the adhesion of Example 1 is excellent, and that the adhesion of Comparative Example 1 and Comparative Example 8 is very poor. Comparative Example 3 shows enhanced adhesion compared to Comparative Example 1, and Comparative Example 4 shows enhanced adhesion compared to Comparative Example 8, but adhesion is deteriorated depending on the type of the substrate.

As is apparent from the relationship of each test specimen and the number of layers for the coating layer, when the number of layers for the coating layer is too small or too large, adhesion is deteriorated. For example, when the number of layers for the coating layer is 12, excellent adhesion resulted.

### [Test Example 2] Measurement of High-Cycle Fatigue Characteristics

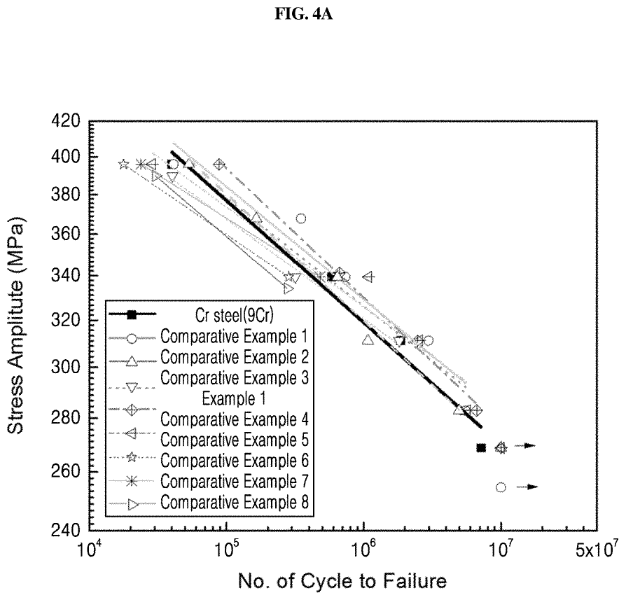

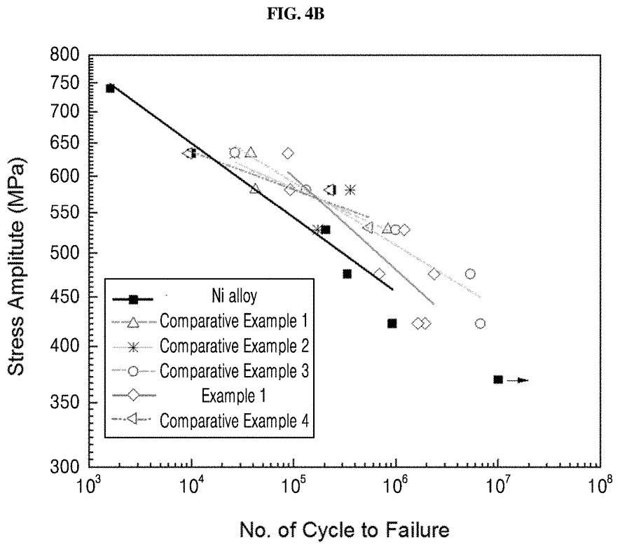

Using a 10-ton capacity universal testing machine, a load is applied in an axial direction to test specimens at a temperature of 600±3° C. and the fatigue characteristics depending on the cycle are measured. The results are shown in FIGS. 4A and 4B. Here, the testing is carried out under the conditions of complete tensile compression with a stress ratio (R ratio) of −1, and the load is applied in the range of 50 to 70% of the tensile strength.

FIG. 4A is a graph showing the measurement results in the case of a chromium steel (9Cr), serving as a substrate, and FIG. 4B is a graph showing the measurement results in the case of a nickel alloy, serving as a substrate.

The high-cycle fatigue characteristic graphs of FIGS. 4A and 4B show that a slope of the fatigue characteristic line of the metal component having the coating layer is similar to that of the fatigue characteristic line of the substrate, and as the fatigue characteristic line of the metal component having the coating layer is located above and to the right of the fatigue characteristic line of the substrate, the fatigue characteristics thereof are determined to be superior.

With reference to FIG. 4A, which is a graph showing high-cycle fatigue characteristics using a chromium steel (9Cr) substrate based on the above-described criteria for determining high-cycle fatigue characteristics, it can be seen that the high-cycle fatigue characteristics of the metal components having the coating layers of Example 1 and Comparative Examples 1 to 5 are superior.

With reference to FIG. 4B, which is a graph showing high-cycle fatigue characteristics using a nickel alloy substrate, high-cycle fatigue characteristic lines of most of the test specimens appear to be located above and to the right of the fatigue characteristic line of the substrate. However, when compared to the slope of the fatigue characteristic line of the substrate, the slopes of the fatigue characteristic lines of the test specimens other than Example 1 and Comparative Example 3 descend remarkably, and thus the high-cycle fatigue characteristics of Example 1 and Comparative Example 3 are deemed to be superior when the nickel alloy is used as a substrate.

As shown in the graphs of FIGS. 4A and 4B, Example 1 and Comparative Example 3 show superior high-cycle fatigue characteristics regardless of a type of substrate. Therefore, the coating layer is configured such that the TiN layer and the TiAlN layer are alternately deposited, in which the total number of layers for the coating layer is 2 to 18, thereby attaining superior high-cycle fatigue characteristics.

### [Test Example 3] Measurement of Residual Stress

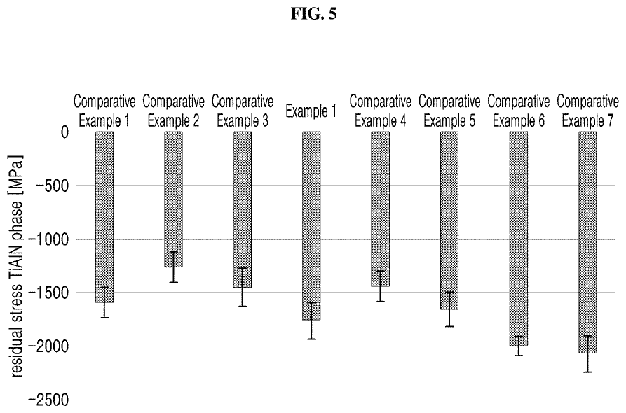

The residual stress of each test specimen is measured by the sin 2Ψ method using X-ray diffraction (XRD). The results are shown in FIG. 5. The sin 2Ψ method is a method of measuring the residual stress of a polycrystalline material, and is described in detail on pages 54 to 66 of “X-ray Stress Measurement Method” (published by Japan Society of Materials Science, 1981, Yokendo Co., Ltd.).

Residual stress is a type of internal stress present in the coating layer, and is expressed as a negative number. When the residual stress of the metal component is −4500 MPa or less, that is, when the absolute value of the residual stress is less than 4500, it can be judged that the residual stress characteristics are superior. As shown in FIG. 5, in all of Comparative Examples 1 to 7 and Example 1, the absolute value of the residual stress measurement value is less than 4500.

Therefore, the residual stress characteristics of the metal component having the coating layer are shown to be superior, but it can be confirmed that the number of layers for the coating layer does not particularly affect the residual stress characteristics.

### [Test Example 4] Measurement of Erosion Characteristics Due to Solid Particles

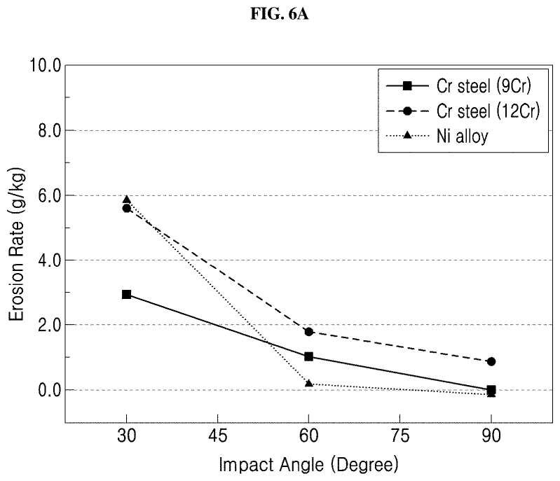

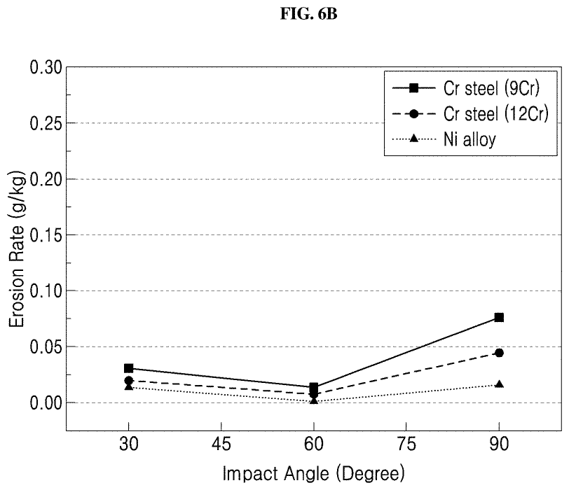

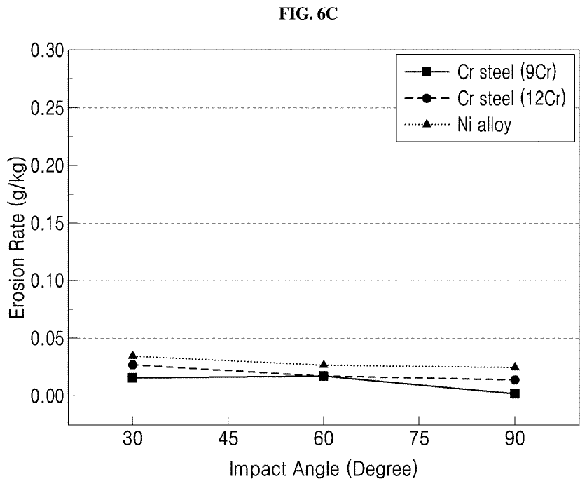

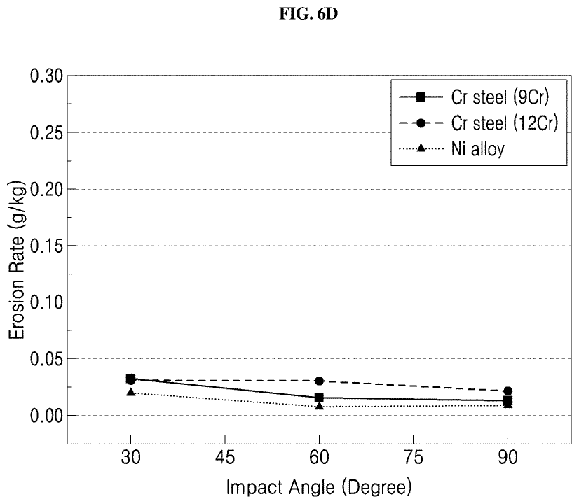

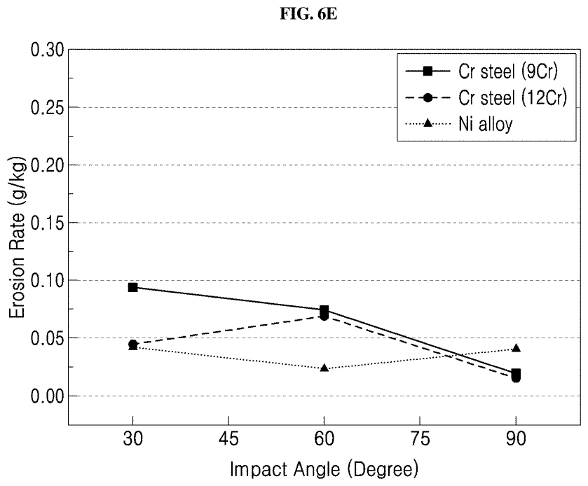

The temperature of each test specimen is maintained at 600±3° C. and 70 μm-sized Fe₃O₄ particles are sprayed onto each test specimen at a rate of 231 m/s to measure the erosion characteristics of the coating layer at a high temperature. The angle of incidence of the particles is set to the range of 30° to 90°. The results are shown in FIGS. 6A to 6E.

FIGS. 6A to 6E are graphs showing the results of measuring the erosion characteristics of a metal substrate, a metal component having the coating layer of Comparative Example 1 formed on the metal substrate, a metal component having the coating layer of Comparative Example 3 formed on the metal substrate, a metal component having the coating layer of Example 1 formed on the metal substrate, and a metal component having the coating layer of Comparative Example 4 formed on the metal substrate, respectively.

As shown in FIGS. 6A to 6E, regardless of the type of the coating layer, the erosion characteristics due to solid particles at a high temperature of the metal components having the coating layers (e.g., FIGS. 6B to 6E) are very superior compared to the metal substrate of FIG. 6A.

However, as shown in FIG. 6B, as the angle of incidence of the particles approached 90°, the erosion characteristics became poor. Also, as shown in FIG. 6E, the erosion characteristics varied depending on the type of substrate. In the substrate made of chromium steel, however, the erosion characteristics are degraded when the angle of incidence is 75° or less.

Meanwhile, as shown in FIGS. 6C and 6D, it is confirmed that the erosion characteristics are finely changed depending on the angle of incidence but that the overall erosion characteristics are superior.

Therefore, when the number of layers for the coating layer comprising the TiN layer and the TiAlN layer, which are alternately deposited, is 2 to 18, erosion characteristics can be expected to be superior at a high temperature. In particular, when the number of layers for the coating layer is 4 or 12, superior high-temperature stability and high erosion resistance can be exhibited.

### [Test Example 5] Measurement of Surface Roughness

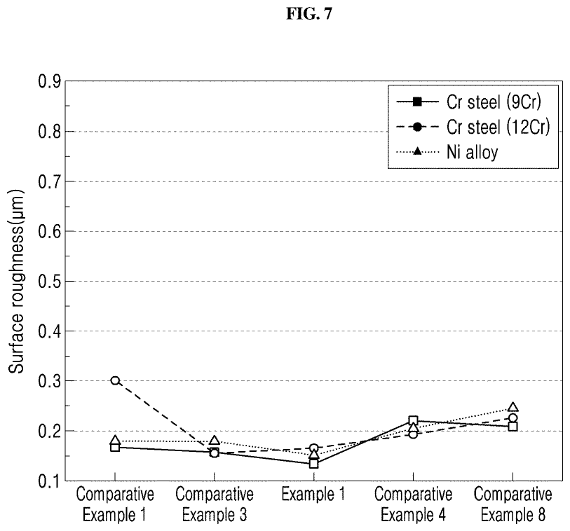

The roughness of each test specimen is measured. The results are shown in FIG. 7.

As shown in FIG. 7, the roughness of the metal components having the coating layers of Comparative Example 3 and Example 1 is lower regardless of the type of substrate.

Therefore, when the number of layers for the coating layer comprising the TiN layer and the TiAlN layer, which are alternately deposited, is 2 to 18, low surface roughness can result. In particular, when the number of layers for the coating layer is 4 or 12, lower surface roughness can be obtained.

### [Test Example 6] Measurement of Hardness

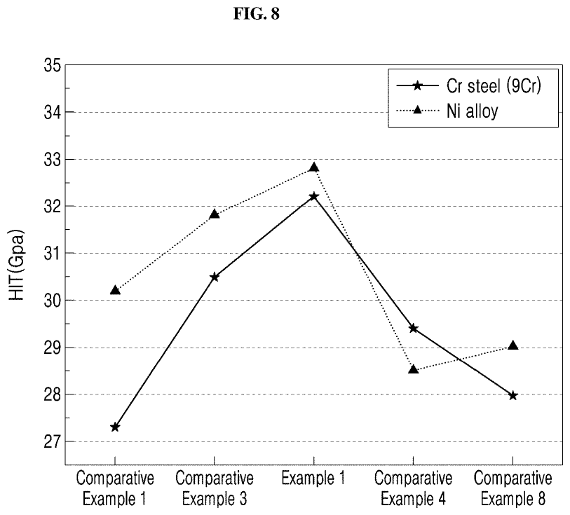

The nano-indentation hardness based on ISO 14577 is measured. The results are shown in FIG. 8. The nano-indentation hardness refers to the hardness determined from the load that is imposed when a triangular-pyramid diamond indenter is pushed into the specimen surface and also from the contact projection area of the indenter and the specimen. In the present embodiment, the measurement is carried out on the micro scale using a nano-indentation hardness tester (Fischerscope® HM 2000). The measurement criteria are shown in Table 3 below.

TABLE 3

| Test load range | 0.1~2000 | mN |
|---|---|---|
| Load accuracy | <40 | μN |
| Indentation depth range | 0.1 nm~150 μm (400 μm) | |
| Approach speed of indenter | <2 | μm/sec |

As shown in FIG. 8, the hardness of Example 1 is the highest regardless of the type of substrate. Referring to the graph of FIG. 8, it can be seen that the hardness decreases from Example 1 toward Comparative Example 1 and toward Comparative Example 8. The total number of layers for the coating layer on the X-axis of the graph is 1, 4, 12, 20, and 28, starting from Comparative Example 1, and thus, when the number of layers for the coating layer is 12, the highest hardness resulted, and as the total number of layers for the coating layer is less than or larger than 12, hardness is decreased.

When the number of layers for the coating layer comprising the TiN layer and the TiAlN layer, which are alternately deposited, is 12, high hardness resulted, but when the number thereof is 4 or 20, hardness is drastically lowered. Hence, it is preferred that the coating layer be composed of 6 to 18 layers. When the coating layer is composed of 12 layers, the highest hardness resulted, thus maximizing abrasion resistance. Accordingly, it is more preferred that 12 layers be formed.

Therefore, the coating layer applied to improve the properties of metal components is configured such that the TiN layer and the TiAlN layer are alternately stacked, in which the total number of layers comprising the TiN layer and the TiAlN layer is 6 to 18, whereby high adhesion, high fatigue resistance, superior residual stress characteristics, high erosion resistance, low surface roughness and high hardness can result. These properties are maximized when the total number of layers is 12.

In order to increase hardness and abrasion resistance, it is preferred that the uppermost layer be a TiAlN layer. Here, it is more preferred that the uppermost TiAlN layer be formed to be thicker than the TiAlN layer positioned in the coating layer.

While exemplary embodiments have been described with reference to the accompanying drawings, it is to be understood by those skilled in the art that various modifications in form and details may be made therein without departing from the sprit and scope as defined by the appended claims. Therefore, the description of the exemplary embodiments should be construed in a descriptive sense and not to limit the scope of the claims, and many alternatives, modifications, and variations will be apparent to those skilled in the art.

What is claimed is:

1. A composite coating layer, comprising:
a TiN layer; and
a TiAlN layer,
wherein the composite coating layer is formed by alternatively stacking the TiN layer and the TiAlN layer, and
wherein a total number of layers comprising the TiN layer and the TiAlN layer is 6 to 18.

2. The composite coating layer of claim 1, wherein the total number of layers comprising the TiN layer and the TiAlN layer, which are alternately stacked, is 12.

3. The composite coating layer of claim 1, wherein a thickness of the TiN layer is 0.1 to 0.5 μm.

4. The composite coating layer of claim 1, wherein a thickness of the TiAlN layer is 0.7 to 3.0 μm.

5. The composite coating layer of claim 1, wherein a total thickness of the composite coating layer is 5.1 to 24.0 μm.

6. The composite coating layer of claim 1, wherein the TiAlN layer comprises 50.3 to 61.5 wt % of Ti, 20.6 to 25.2 wt % of Al, and 19.1 to 23.3 wt % of N.

7. The composite coating layer of claim 1, wherein an uppermost layer of the composite coating layer is a TiAlN layer.

8. The composite coating layer of claim 7, wherein a thickness of the uppermost TiAlN layer is 1.0 to 6.0 μm.

9. A turbine component, comprising:
a substrate; and
a composite coating layer disposed on the substrate,
wherein the composite coating layer is formed by alternatively stacking a TiN layer and a TiAlN layer, and
wherein a total number of layers comprising the TiN layer and the TiAlN layer is 6 to 18.

10. The turbine component of claim 9, wherein the total number of layers comprising the TiN layer and the TiAlN layer, which are alternately stacked, is 12.

11. The turbine component of claim 9, wherein the substrate is chromium steel or a nickel alloy.

12. The turbine component of claim 9, wherein a thickness of the TiN layer is 0.1 to 0.5 μm.

13. The turbine component of claim 9, wherein a thickness of the TiAlN layer is 0.7 to 3.0 μm.

14. The turbine component of claim 9, wherein a total thickness of the composite coating layer is 5.1 to 24.0 μm.

15. The turbine component of claim 9, wherein the TiAlN layer comprises 50.3 to 61.5 wt % of Ti, 19.6 to 26.2 wt % of Al, and 18.8 to 24.3 wt % of N.

16. The turbine component of claim 9, wherein an uppermost layer of the composite coating layer is a TiAlN layer.

17. The turbine component of claim 16, wherein a thickness of the uppermost TiAlN layer is 1.0 to 6.0 μm.

18. The turbine component of claim 9, wherein the turbine component is a bucket or a nozzle.

19. The turbine component of claim 9, wherein the turbine component is used for a turbine blade or a turbine vane.

20. The turbine component of claim 9, wherein the turbine component is used for an electrical turbine, a gas turbine, or a steam turbine.
